(19) United States
(12) Patent Application Publication
(10) Pub. No.: US 2025/0287718 A1
(43) Pub. Date: Sep. 11, 2025

(54) SOLID-STATE IMAGE SENSOR

(71) Applicant: SAMSUNG ELECTRONICS CO., LTD., Suwon-si (KR)

(72) Inventor: Kazufumi Shiozawa, Yokohama (JP)

(21) Appl. No.: 19/065,804

(22) Filed: Feb. 27, 2025

(30) Foreign Application Priority Data
Mar. 5, 2024 (JP) 2024-032694
Jun. 4, 2024 (KR) 10-2024-0073182

(51) Int. Cl. H10F 39/00

(52) U.S. Cl. CPC H10F 39/811; H10F 39/8063

(57) ABSTRACT

A solid-state image sensor is configured to reduce the occurrence of stray light or color mixing by appropriately reflecting light from a wiring layer. The solid-state image sensor includes a plurality of photoelectric conversion units arranged two-dimensionally, an on-chip lens formed on one side of the photoelectric conversion unit, wiring layers formed on another side of the photoelectric conversion unit; and a first periodic structure formed in a first wiring layer of the wiring layers, the first periodic structure having periodicity in a two-dimensional direction that is perpendicular to a stacking direction. Among the wiring layers, the first wiring layer is closest to the photoelectric conversion unit. The first periodic structure includes a metal layer and a dielectric layer, each of which is provided in plurality, the metal layer including a metal, and the dielectric layer including a dielectric material.

### CROSS-REFERENCE TO RELATED APPLICATION

This application is based on and claims priority under 35 U.S.C. § 119 to Japanese Patent Application No. 2024-032694, filed on Mar. 5, 2024, in the Japan Patent Office, and Korean Patent Application No. 10-2024-0073182, filed on Jun. 4, 2024, in the Korean Intellectual Property Office, the disclosures of which are incorporated by reference herein in their entirety.

### BACKGROUND

A solid-state image sensor may be mounted in various mobile terminals, such as digital cameras or portable phones. In general, a solid-state image sensor may include a plurality of photoelectric conversion units arranged two-dimensionally, an on-chip lens formed on a light-incident side of a photoelectric conversion unit, and a wiring layer formed on another side of the photoelectric conversion unit, which is opposite to the light-incident side on which the on-chip lens is formed.

### SUMMARY

In some solid-state image sensors, part of the light that is not absorbed by a photoelectric conversion unit may be reflected by a wiring layer and return to the photoelectric conversion unit. In this case, due to the insufficient reflection of light at the wiring layer, stray light or color mixing may occur. The present disclosure provides a solid-state image sensor that may reduce the occurrence of stray light or color mixing by appropriately reflecting light from a wiring layer.

In a first general aspect, a solid-state image sensor includes: a plurality of photoelectric conversion units arranged two-dimensionally, an on-chip lens formed on one side of the photoelectric conversion unit, wiring layers formed on another side of the photoelectric conversion unit, and a first periodic structure formed in a first wiring layer of the wiring layers, the first periodic structure having periodicity in a two-dimensional direction that is perpendicular to a stacking direction, wherein, among the wiring layers, the first wiring layer is closest to the photoelectric conversion unit, wherein the first periodic structure includes a metal layer and a dielectric layer, each of which is provided in plurality, the metal layer including a metal, and the dielectric layer including a dielectric material.

In a second general aspect, a solid-state image sensor includes: a plurality of photoelectric conversion units arranged two-dimensionally, an on-chip lens formed on one side of the photoelectric conversion unit, wiring layers formed on another side of the photoelectric conversion unit, and a first periodic structure formed in an interlayer film located between the photoelectric conversion unit and a first wiring layer of the wiring layers, the first periodic structure having periodicity in a two-dimensional direction that is a perpendicular to a stacking direction, wherein, among the wiring layers, the first wiring layer is closest to the photoelectric conversion unit, wherein the first periodic structure includes a high-refractive-index layer and a low-refractive-index layer, each of which is provided in plurality, and the high-refractive-index layer has a higher refractive index than the low-refractive-index layer.

Implementation of the disclosed solid-state image sensor may include one or more of the following features.

In some implementations, a shape of the metal layers of the first periodic structure includes an island shape in which each of the metal layers is independently arranged, or a peninsula shape, a ring shape, or a linear shape in which the metal layers are connected to each other.

In some implementations, the metal layer of the first periodic structure may include a wiring for a sensor operation and a dummy wiring that does not contribute to the sensor operation.

In some implementations, a width of the metal layer of the first periodic structure may be greater than a width of the dielectric layer.

In some implementations, a period of the metal layer of the first periodic structure may vary depending on wavelength and an incidence angle of light received by the photoelectric conversion unit and be shorter than the wavelength, and light irradiated to the first periodic structure may be set to generate diffracted light in the first periodic structure.

In some implementations, a period of the first periodic structure may be different in a pixel array central portion and a pixel array peripheral portion in each of the plurality of photoelectric conversion units arranged two-dimensionally, wherein the pixel array peripheral portion may be around the pixel array central portion.

In some implementations, when a wavelength of light received by the photoelectric conversion unit is 940 nm, a height of the first periodic structure may be in a range of about 100 nm to about 1500 nm.

In some implementations, when a wavelength of light received by the photoelectric conversion unit is 940 nm, a height of the first periodic structure may satisfy a reflectance of 70% or more.

In some implementations, the solid-state image sensor may further include a second periodic structure formed in an interlayer film located between the photoelectric conversion unit and the first wiring layer, the second periodic structure having periodicity in a two-dimensional direction that is perpendicular to the stacking direction, wherein the second periodic structure includes a high-refractive-index layer and a low-refractive-index layer, each of which is provided in plurality, and the high-refractive-index layer has a higher refractive index than the low-refractive-index layer.

In some implementations, a shape of the high-refractive-index layer of the second periodic structure may include an island shape in which each of high-refractive-index layers is independently arranged, or a peninsula shape, a ring shape, or a linear shape in which the high-refractive-index layers are connected to each other.

In some implementations, a period of the second periodic structure may vary depending on wavelength and an incidence angle of light received by the photoelectric conversion unit and be shorter than the wavelength, and light irradiated to the second periodic structure is set to generate diffracted light in the second periodic structure.

In some implementations, a period of the second periodic structure may be different in a pixel array central portion and a pixel array peripheral portion in each of the plurality of photoelectric conversion units arranged two-dimensionally, wherein the pixel array peripheral portion may be around the pixel array central portion.

In some implementations, a distance from a bottom surface of the photoelectric conversion unit to the first periodic structure and a distance from the bottom surface of the photoelectric conversion unit to the second periodic structure may be integer multiples of a half wavelength of incident light.

In some implementations, the second periodic structure may have a concavo-convex shape, and, when a wavelength of light received by the photoelectric conversion unit is 940 nm, a height of a convex portion of the concavo-convex shape may be in a range of about 200 nm to about 400 nm or a range of about 1000 nm to about 1200 nm.

In some implementations, the second periodic structure may have a concavo-convex shape, and, when a wavelength of light received by the photoelectric conversion unit is 940 nm, a height of a convex portion of the concavo-convex shape may satisfy a reflectance of 70% or more.

In some implementations, a shape of the high-refractive-index layers of the first periodic structure may include an island shape in which each of high-refractive-index layers is independently arranged, or a peninsula shape, a ring shape, or a linear shape in which the high-refractive-index layers are connected to each other.

In some implementations, a period of the first periodic structure may vary depending on wavelength and an incidence angle of light received by the photoelectric conversion unit and be shorter than the wavelength, and light irradiated to the first periodic structure may be set to generate diffracted light in the first periodic structure.

In some implementations, a period of the first periodic structure may be different in a pixel array central portion and a pixel array peripheral portion of each of the plurality of photoelectric conversion units arranged two-dimensionally, wherein the pixel array peripheral portion may be around the pixel array central portion.

In some implementations, the first periodic structure may be a concavo-convex shape, and, when a wavelength of light received by the photoelectric conversion unit is 940 nm, a height of a convex portion of the concavo-convex shape is in a range of about 200 nm to about 400 nm, is in a range of about 1000 nm to about 1200 nm, or satisfies a reflectance of 70% or more.

### BRIEF DESCRIPTION OF THE DRAWINGS

FIG. 1 is a front cross-sectional view of an example of a solid-state image sensor.

FIG. 2 is a plan view of an example of a wiring layer of a solid-state image sensor.

FIG. 3 is a plan view of another example of a wiring layer of a solid-state image sensor.

FIG. 4 is a schematic front view of an example of a wiring layer of a solid-state image sensor, when a pitch of a metal layer is relatively short.

FIG. 5 is a plan view of an example of a pixel region including a plurality of pixels.

FIG. 6 is a graph showing an example of a relationship between pitch and reflectance of a first periodic structure when an incidence angle is changed to 4 types.

FIG. 7 is a graph showing an example of a relationship between height and reflectance of a metal layer of a first periodic structure.

FIG. 8 is a schematic front view of an example of a second periodic structure of a solid-state image sensor.

FIG. 9 is a graph showing an example of a relationship between pitch and reflectance of a second periodic structure when an incidence angle is changed to 4 types.

FIG. 10 is a graph showing an example of a relationship between height and reflectance of a convex portion of a second periodic structure.

FIG. 11 is a schematic cross-sectional view showing an example of the reflection of incident light from a first periodic structure and a second periodic structure.

FIG. 12 is a graph showing an example of a relationship between pitch and reflectance when an incidence angle is changed to 4 types and a first periodic structure and a second periodic structure have the same pitch.

FIG. 13 is a front cross-sectional view of a solid-state image sensor according to a comparative example.

FIG. 14 is a plan view of a comparative example a wiring layer of a solid-state image sensor according to a comparative example.

FIG. 15 is a schematic cross-sectional view of an example of a second periodic structure of a solid-state image sensor.

FIG. 16 is a plan view of an example of a first periodic structure.

FIG. 17 is a plan view of another example of a first periodic structure.

FIG. 18 is a plan view of another example of a first periodic structure.

FIG. 19 is a plan view of another example of a first periodic structure.

FIG. 20 is a plan view of another example of a first periodic structure.

FIG. 21 is a plan view of an example of a second periodic structure.

FIG. 22 is a plan view of another example of a second periodic structure.

FIG. 23 is a plan view of another example of a second periodic structure.

Dimensional ratios in the drawings may be exaggerated for clarity and may differ from actual ratios.

### DETAILED DESCRIPTION

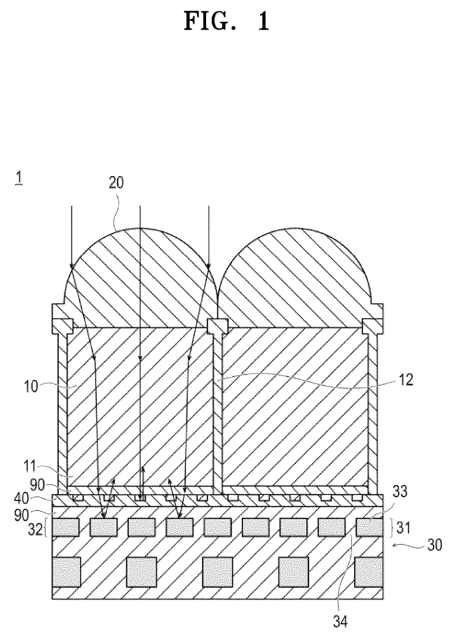

With reference to FIG. 1, a solid-state image sensor 1 may be a complementary metal-oxide-semiconductor (CMOS)-type solid-state image sensor. The solid-state image sensor 1 includes a plurality of photoelectric conversion units 10 arranged two-dimensionally, an on-chip lens 20 formed on the photoelectric conversion unit 10, a first periodic structure 32, a wiring layer 30 formed under the photoelectric conversion unit 10, and a second periodic structure 40 formed in an interlayer film 90, e.g., an interlayer insulating film, that is between the photoelectric conversion unit 10 and the wiring layer 30. The interlayer film 90 may include a dielectric material or an insulator.

The photoelectric conversion unit 10 may be formed in plurality in a substrate 11. The substrate 11 may be, for example, a semiconductor substrate, such as a silicon (Si) substrate. In FIG. 1, a lower surface of the substrate 11 may be a front side surface of the substrate 11, while an upper surface of the substrate 11 may be a back side surface of the substrate 11. Because the solid-state image sensor 1 in this example is a so-called backside illumination type, the on-chip lens 20 may be formed on the back side of the substrate 11. The back side of the substrate 11 may be a light incidence surface of the substrate 11. Moreover, the wiring layer 30 may be formed on a surface side of the substrate 11. The substrate 11 may have a thickness of, for example, about 1 μm to about 6 μm.

The photoelectric conversion unit 10 may be formed for each pixel in the substrate 11. The photoelectric conversion unit 10 may include a p-type semiconductor region and an n-type semiconductor region. In the photoelectric conversion unit 10, a photodiode may be realized by a pn junction between the p-type semiconductor region and the n-type semiconductor region and convert light into charges. The photoelectric conversion unit 10 may receive light incident to the on-chip lens 20, generate signal charges according to the amount of light received, and accumulate the generated signal charges in the n-type semiconductor region.

Adjacent ones of the photoelectric conversion units 10 may be separated from each other by an insulating film 12 as shown in FIG. 1. Accordingly, it may be difficult for signal charges to flow from one pixel into adjacent pixels. For this reason, when signal charges exceeding a saturation charge amount are generated, the flow of signal charges from the photoelectric conversion unit 10 in which signal charges are overflowing, into the photoelectric conversion unit 10 adjacent thereto may be reduced. Accordingly, color mixing between pixels may be inhibited from occurring. A constituent material of the insulating film 12 may include a silicon oxide film, a silicon nitride film, a silicon oxynitride film, or a resin film. The insulating film 12 may include a film that has no or few positive fixed charges.

Furthermore, a fixed charge film may be formed between adjacent ones of the photoelectric conversion units 10. The fixed charge film may reduce the generation of a dark current and reduce noise. A constituent material of the fixed charge film may include, for example, an oxide film or nitride film including at least one metal element of hafnium (Hf), aluminum (Al), zirconium (Zr), tantalum (Ta), and titanium (Ti). Methods of forming the fixed charge film may include, for example, a chemical vapor deposition (CVD) process, a sputtering process, and an atomic layer deposition (ALD) process.

The on-chip lens 20 may be formed for each pixel. The on-chip lens 20 may condense incident light. The light condensed by the on-chip lens 20 may be incident to the photoelectric conversion unit 10.

In addition, a light blocking film and a planarization film may be formed between the on-chip lens 20 and the photoelectric conversion unit 10.

The wiring layer 30 may include a plurality of wiring layers in a stacking direction as shown in FIG. 1. From among the plurality of wiring layers 30 formed in the stacking direction, a first periodic structure 32 may be formed in a first wiring layer 31 that is closest to the photoelectric conversion unit 10.

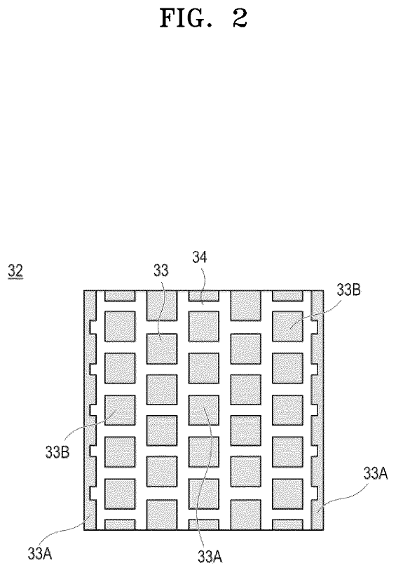

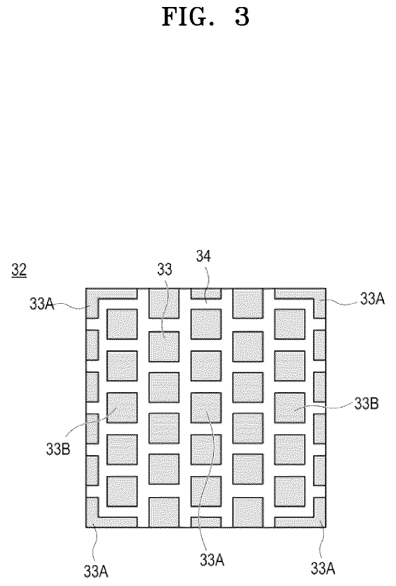

As shown in FIG. 2, the first periodic structure 32 may have periodicity in a two-dimensional direction (plane direction) that is perpendicular to the stacking direction. As shown in FIGS. 2 and 3, the first periodic structure 32 may include a metal layer 33 and a dielectric layer 34. The metal layer 33 and the dielectric layer 34 may be formed in plurality.

As shown in FIGS. 2 and 3, each of metal layers 33 may be independently arranged in an island shape, e.g., not contacting each other and separated by the dielectric layer 34. The metal layers 33 may be arranged in a zigzag shape, e.g., adjacent metal layers 33 are offset from each other in both horizontal directions.

The metal layer 33 may include a wiring for a sensor operation and a dummy wiring that does not contribute to the sensor operation. In FIG. 2, for example, wirings 33A for a sensor operation may be located in the center and both sides of the first periodic structure 32, and dummy wirings 33B may be formed in remaining locations, e.g., between wirings 33A. In FIG. 3, for example, wirings 33A for a sensor operation may be located in the center and four corners of the first periodic structures 32, and dummy wirings 33B may be formed in remaining locations. When the wiring layer 30 is formed, it may be necessary to maintain a coverage of the metal layer 33 within a predetermined range to flatten a film thickness, and a dummy wiring may be formed such that the coverage of the metal layer 33 is maintained within the predetermined range.

As shown in FIGS. 2 and 3, the dielectric layer 34 may be linearly arranged along an outer circumference of the metal layer 33 having an island shape. The dielectric layer 34 may be linearly arranged to partition the metal layer 33.

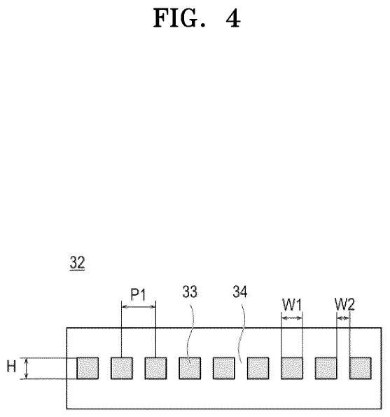

As shown in FIG. 4, a width W1 of the metal layer 33 of the first periodic structure 32 may be greater than a width W2 of the dielectric layer 34. According to the configuration described above, because an area occupied by the metal layer 33 contributing to reflection is greater than an area occupied by the dielectric layer 34, incident light may be appropriately reflected by the first periodic structure 32.

Assuming that a refractive index of the dielectric layer 34 is n1, an incidence angle of incident light is θ, the diffraction order m is a natural number, a wavelength of incident light is λ, and a refractive index of the metal layer 33 is n2, a pitch P1 of the metal layer 33 in a horizontal plane direction may satisfy Equation 1 below:

$$n 1 sin θ \pm \frac{m λ}{P 1} = \sqrt{\frac{n {1}^{2} \times n {2}^{2}}{n {1}^{2} + n {2}^{2}}} \qquad [ Equation 1 ]$$

When the periodic relationship defined by Equation 1 is satisfied, light that is incident on the first periodic structure 32 can be diffracted by the metal layer 33 in the first periodic structure 32 and may move in a lateral direction, thereby generating evanescent waves. Accordingly, light intensity may be enhanced due to surface plasmon resonance, and thus, the incident light may be more appropriately reflected by the first periodic structure 32.

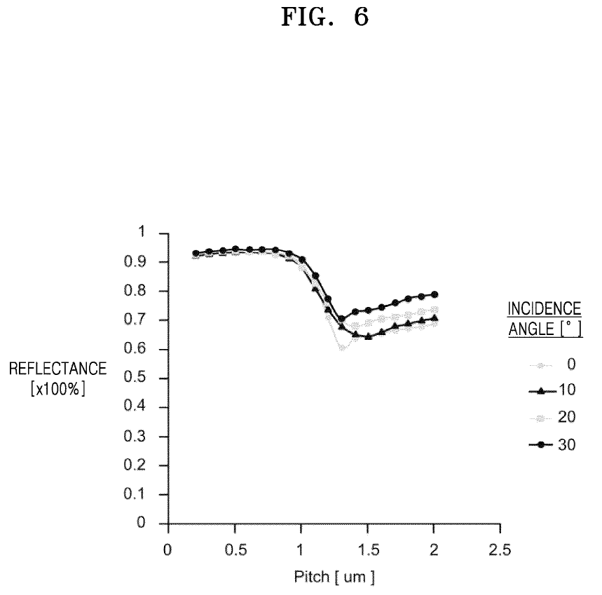

In other words, the pitch P1 of the metal layer 33 of the first periodic structure 32 may be selected depending on the wavelength λ and the incidence angle θ of light received by the photoelectric conversion unit 10. The pitch P1 can be shorter than the wavelength λ. Also, light irradiated to the first periodic structure 32 may generate diffracted light in the first periodic structure 32. As a result, the above-described effect of surface plasmon resonance may be obtained. In addition, reflectance may be improved by adjusting the pitch P1 of the metal layer 33 of the first periodic structure 32 to a dimension smaller than wavelength λ. As shown in FIG. 6, when the wavelength λ of the incident light is 940 nm, the pitch P1 of the metal layer 33 may be in a range of about 200 nm to about 1000 nm and be, for example, in a range of about 400 nm to about 500 nm.

As shown in FIG. 6, when the pitch P1 of the first periodic structure 32 is constant, a reflectance of the first periodic structure 32 may vary depending on an incidence angle θ. FIG. 6 is a graph of simulation results showing the reflectance of the first periodic structure 32 when the pitch P1 and the incidence angle θ are appropriately changed.

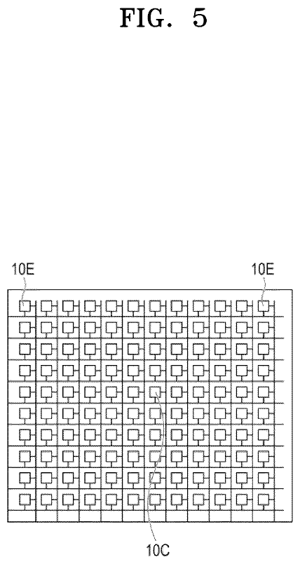

Because the reflectance of the first periodic structure 32 varies depending on the incidence angle θ, to improve reflectance, the pitch P1 of the first periodic structure 32 may be different in a pixel array central portion (refer to pixel array central portion 10C in FIG. 5) and a pixel array peripheral portion (refer to pixel array peripheral portion 10E in FIG. 5), which is around the pixel array central portion 10C, in each of the plurality of photoelectric conversion units 10 arranged two-dimensionally. This may be due to the fact that the incidence angle θ of the pixel array central portion 10C is different from the incidence angle θ of the pixel array peripheral portion 10E. According to the configuration described above, the effect of surface plasmon resonance may be appropriately displayed in all pixels, and the reflectance of the first periodic structure 32 may improve.

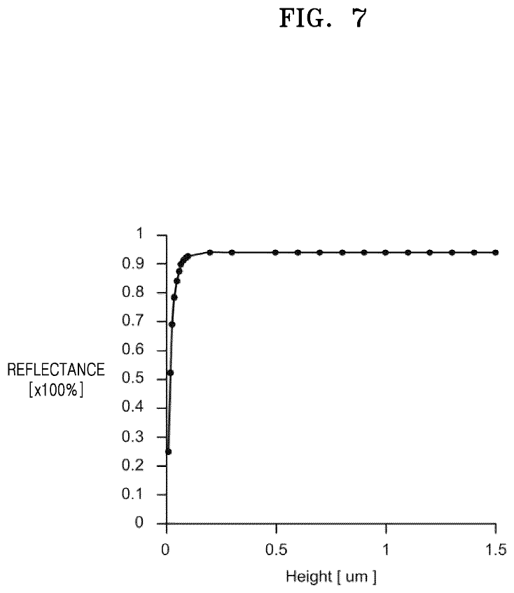

Next, a height (refer to H in FIG. 4) of the first periodic structure 32 is described with reference to FIG. 7. FIG. 7 is a graph of simulation results showing the reflectance of the first periodic structure 32 when the height H of the first periodic structure 32 is appropriately changed.

When a wavelength λ of light incident to a photoelectric conversion unit 10 is 940 nm, a height H of the first periodic structure 32 may be in a range of about 100 nm to about 1500 nm. According to the numerical range described above, the reflectance of the first periodic structure 32 may improve. The height H of the first periodic structure 32 is not limited to the numerical range described above and may be selected to satisfy a reflectance of 70% or more.

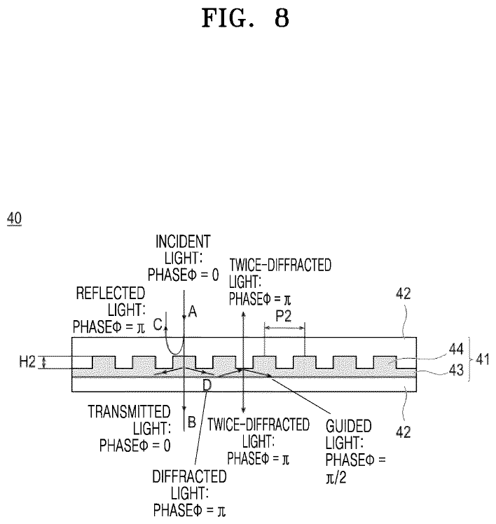

Next, a configuration of the second periodic structure 40 is described with reference to FIGS. 8 to 10. As shown in FIG. 1, the second periodic structure 40 may be formed in the interlayer film 90 located between the photoelectric conversion unit 10 and the first wiring layer 31. The second periodic structure 40 may have periodicity in a two-dimensional direction that is perpendicular to a stacking direction.

As shown in FIG. 8, the second periodic structure 40 may include a high-refractive-index layer 41 and a low-refractive-index layer 42. The high-refractive-index layer 41 may have a higher refractive index than the low-refractive-index layer 42.

A constituent material of the high-refractive-index layer 41 may include a silicon nitride film. A constituent material of the low-refractive-index layer 42 may include a silicon oxide film.

As shown in FIG. 8, the high-refractive-index layer 41, e.g., a diffraction grating, may include a flat portion 43 and convex portions 44, e.g., a ridge of the diffraction grating, each of which has a convex shape with respect to the flat portion 43, e.g., a line segment between any two distinct points on the boundary of the convex portions 44 is above the flat portion 43. Each of the convex portions 44 may be independently arranged in an island shape. As a result, the overall shape of the high-refractive-index layer 41 is concavo-convex, e.g., alternative between convex regions and flat portions, so that the height of the high-refractive-index layer 41 alternates.

The flat portion 43 and the convex portions 44 of the high-refractive-index layer 41 may be inserted into the low-refractive-index layer 42 as shown in FIG. 8.

Hereinafter, a mechanism by which the second periodic structure 40 functions as a guided mode resonance grating is described with reference to FIG. 8.

When incident light is incident to the second periodic structure 40 configured as described above, light may be incident from the low-refractive-index layer 42 to the high-refractive-index layer 41, and thus, a phase difference may not occur in a phase of transmitted light. A phase difference π may occur in a phase Φ of reflected light, which is reflected by the high-refractive-index layer 41 and returns to the low-refractive-index layer 42. In addition, a phase difference π/2 may occur in the phase Φ of light diffracted by the second periodic structure 40.

Accordingly, assuming that a phase Φ of incident light A is 0, a phase Φ of transmitted light B may become 0, and a phase Φ of reflected light C may become π. Also, a phase Φ of light D diffracted by the convex portion 44 may become π/2. Furthermore, when the diffracted light D is guided within the convex portion 44 and enters the convex portion 44 again, part of the diffracted light D may be newly diffracted upward and downward in the convex portion 44. As a result, the phase Φ of the diffracted light D may become π. Moreover, the diffracted light D may be repeatedly guided within the convex portion 44 and diffracted again by the convex portion 44 upward and downward in the convex portion 44, and thus, the phase Φ of the diffracted light D may become π.

Therefore, light emitted downward from the second periodic structure 40 includes a mixture of transmitted light B with a phase Φ of 0 and diffracted light D with a phase Φ of π. Thus, the transmitted light B and the diffracted light D may de-constructively interfere with other. In contrast, all light emitted upward from the second periodic structure 40 may have a phase Φ of π and constructively interfere with each other.

When light diffracted by the convex portion 44 satisfies the guided mode by satisfying the total reflection condition within the convex portion 44, transmission of incident light A having a wavelength λ may be inhibited (or blocked) in the second periodic structure 40, and most of the incident light A may be reflected.

In addition, the reflection of light may be achieved when a wavelength of incident light, a period and height of the second periodic structure 40, a width of the convex portion 44, and a height of the flat portion 43 meet specific conditions.

A pitch P2 of the convex portion 44 of the high-refractive-index layer 41 may vary depending on a wavelength λ and incidence angle θ of light received by the photoelectric conversion unit 10 and also, be shorter than the wavelength λ. Also, light irradiated to the second periodic structure 40 may be selected to generate diffracted light in the second periodic structure 40. Because much diffracted light is generated due to the configuration described above, the incident light may be appropriately reflected by the second periodic structure 40. When the wavelength λ of the incident light is 940 nm, the pitch P2 of the convex portion 44 may be in a range of about 400 nm to about 800 nm.

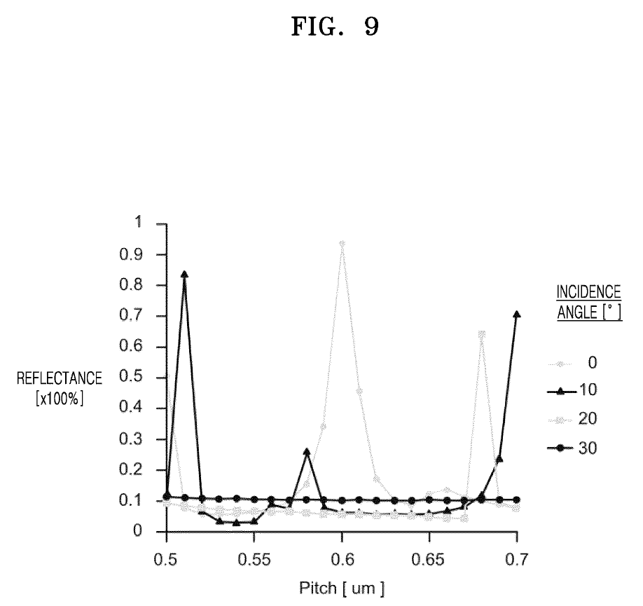

As illustrated in FIG. 9, when the pitch P2 of the convex portion 44 of the second periodic structure 40 is constant, a reflectance of the second periodic structure 40 may vary depending on an incidence angle θ. FIG. 9 is a graph of simulation results showing the reflectance of the second periodic structure 40 when the pitch P2 and the incidence angle θ are appropriately changed.

Because the reflectance of the second periodic structure 40 varies depending on the incidence angle θ and the pitch P2 of the second periodic structure 40, to improve reflectance, the pitch P2 of the second periodic structure 40 may be different in a pixel array central portion 10C and a pixel array peripheral portion 10E, which is around the pixel array central portion 10C, in each of the plurality of photoelectric conversion units 10 arranged two-dimensionally. This may be due to the fact that the incidence angle θ of the pixel array central portion 10C is different from the incidence angle θ of the pixel array peripheral portion 10E. According to the configuration described above, the reflectance of the second periodic structure 40 may improve.

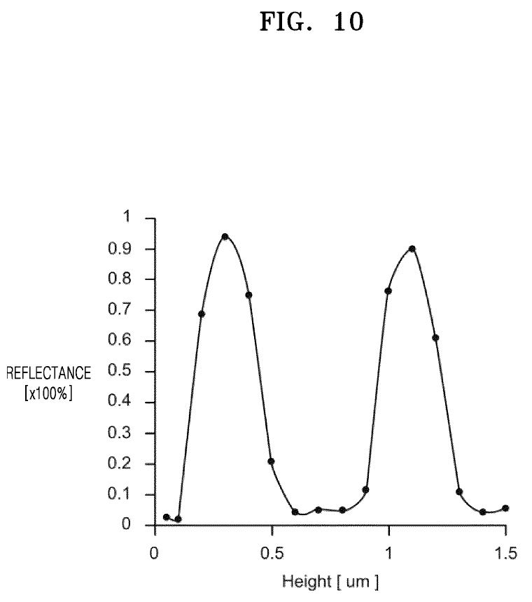

Next, a height (refer to H2 in FIG. 8) of the convex portion 44 of the second periodic structure 40 is described with reference to FIG. 10. FIG. 10 is a graph of simulation results showing the reflectance of the second periodic structure 40 when the height H2 of the convex portion 44 of the second periodic structure 40 is appropriately changed.

When a wavelength λ of light incident to the photoelectric conversion unit 10 is 940 nm, the height H2 of the convex portion 44 of the second periodic structure 40 may be in a range of about 200 nm to about 400 nm or a range of about 1000 nm to about 1200 nm. According to the numerical range described above, the reflectance of the second periodic structure 40 may improve. The height H2 of the second periodic structure 40 is not limited to the numerical range described above and may be set to satisfy a reflectance of 70% or more.

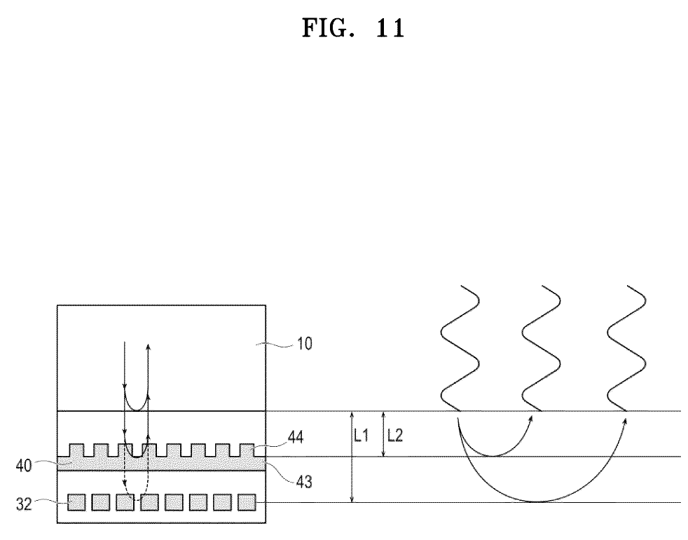

As illustrated in FIG. 11, a distance L1 from a bottom surface of the photoelectric conversion unit 10 to the center of the first periodic structure 32 and a distance L2 from the bottom surface of the photoelectric conversion unit 10 to the flat portion 43 of the second periodic structure 40 may be integer multiples of a half wavelength of incident light. According to the configuration described above, phases of light reflected by an interface between the photoelectric conversion unit 10 and the low-refractive-index layer 42, light reflected by the first periodic structure 32, and light reflected by the second periodic structure 40 may gather and strengthen each other. Therefore, light intensity in the photoelectric conversion unit 10 may further improve.

Next, the behavior of incident light when light is incident to this example of the solid-state image sensor 1 is described with reference to FIG. 11.

To begin, light may be irradiated from a back side (or an upper part of FIG. 11) of the substrate 11 and be incident to the on-chip lens 20 (not shown in FIG. 11). The light incident to the on-chip lens 20 may be condensed by the on-chip lens 20 and enter the photoelectric conversion unit 10. The photoelectric conversion unit 10 may convert incident light into charges by photoelectric conversion and generate signal charges. The signal charges may be output as a pixel signal through the wiring layer 30 formed on a surface of the substrate 11.

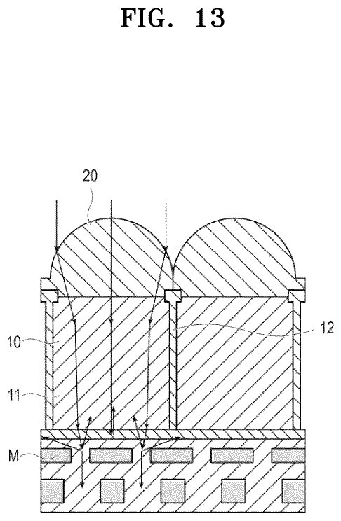

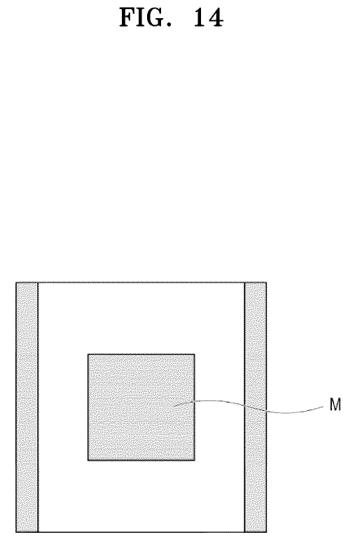

For example, as illustrated in FIGS. 13 and 14, when the first periodic structure 32 and the second periodic structure 40 are replaced with a reflective mirror M having a great width is located in the center (e.g., of a solid-state image sensor), part of light that was not absorbed by a photoelectric conversion unit may be reflected by a wiring layer and return to the photoelectric conversion unit. However, due to the insufficient reflection of light at the wiring layer, stray light or color mixing may be likely to occur (refer to arrows in FIG. 13).

In contrast, in the solid-state image sensor 1 disclosed herein, by forming the first periodic structure 32 and the second periodic structure 40 as shown in FIG. 11, e.g., as opposed to reflective mirrors M, incident light may be reflected by the first periodic structure 32 and the second periodic structure 40 and return to the photoelectric conversion unit 10, and thus, the occurrence of stray light or color mixing may be reduced.

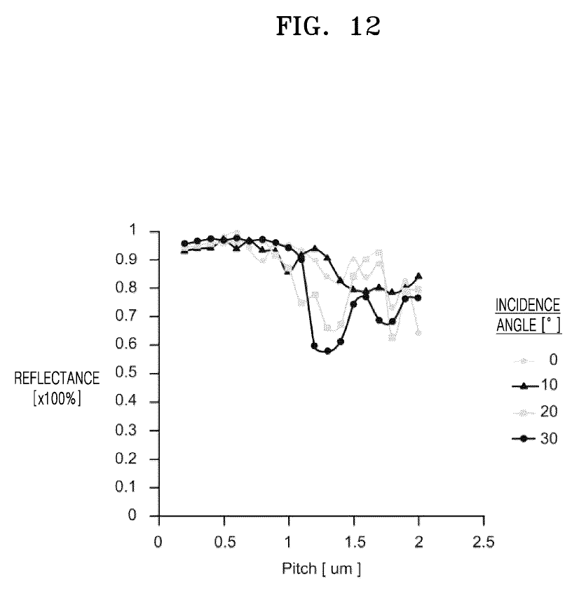

By arranging the first periodic structure 32 and the second periodic structure 40, the influence of the incidence angle θ may be reduced as shown in FIG. 12, and thus, reflectance may improve. FIG. 12 is a graph of simulation results showing the reflectances of the first periodic structure 32 and the second periodic structure 40 when the pitch and the incidence angle θ of the first periodic structure 32 and the second periodic structure 40 are appropriately changed.

Various modifications to the previous examples may be made without departing from the spirit of the present disclosure.

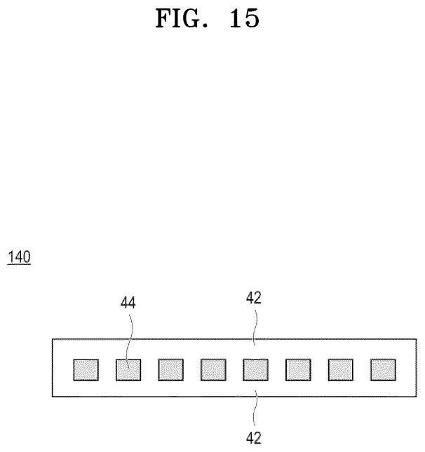

For example, in the above-described example, although the second periodic structure 40 includes the flat portion 43 and the convex portions 44, a second periodic structure 140 may include only the convex portions 44 without forming the flat portion 43 as shown in FIG. 15.

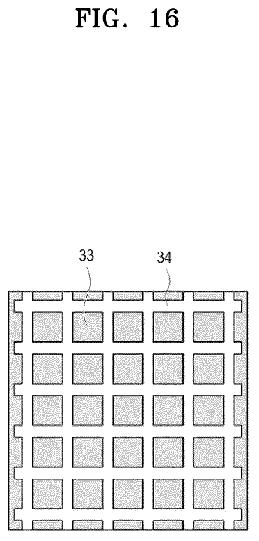

In the above-described example, a metal layer 33 may be arranged in a zigzag shape in the first periodic structure 32. However, as shown in FIG. 16, the metal layer 33 may have a square arrangement.

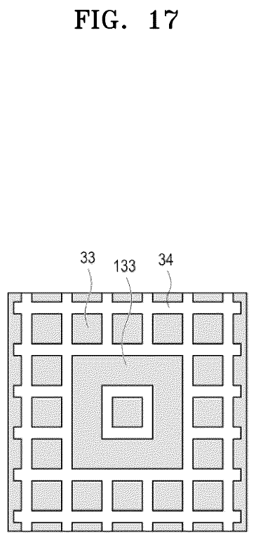

In the above-described example, the metal layer 33 may have an island shape. However, a metal layer 133 may have a ring shape as shown near the center of FIG. 17.

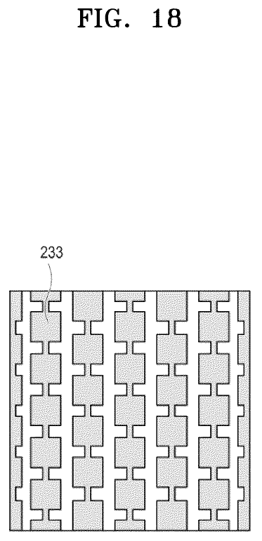

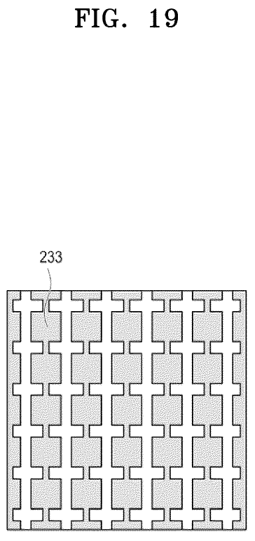

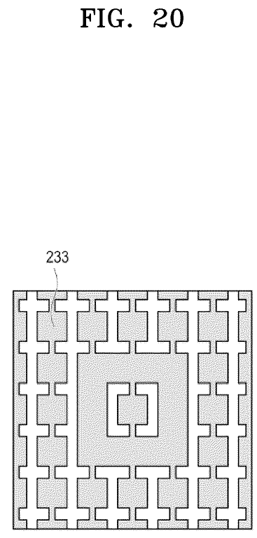

In the above-described example, the metal layer 133 may have an island shape. However, as illustrated in FIGS. 18 to 20, metal layers 233 may each have a peninsula shape and be connected to each other. FIG. 18 corresponds to a modified example of the peninsular shape of FIG. 2, FIG. 19 corresponds to a modified example of the peninsula shape of FIG. 16, and FIG. 20 corresponds to a modified example of the peninsula shape of FIG. 17.

In the above-described example, the metal layer 233 may have an island shape. However, a metal layer may have a linear shape.

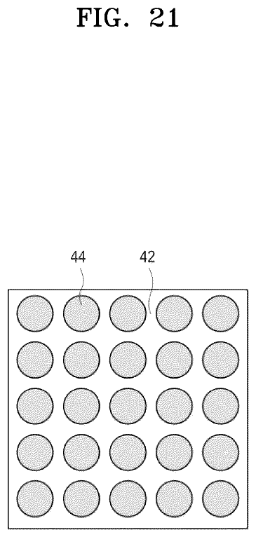

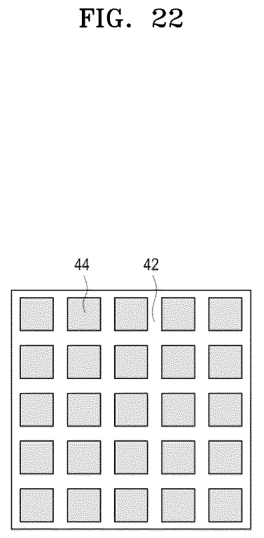

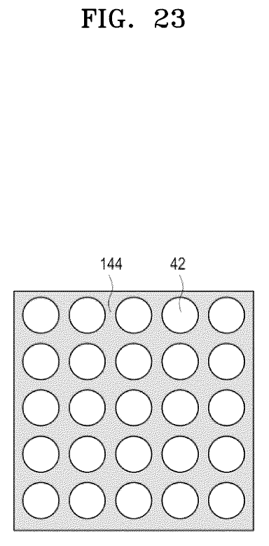

When the second periodic structure 140 includes only the convex portions 44 as illustrated in FIG. 15, a shape of the convex portion 44 may include an island shape in which each of the convex portions 44 is independently arranged as shown in FIG. 21 and may be a circular shape shown in FIG. 21 or a rectangular shape shown in FIG. 22. Furthermore, as illustrated in FIG. 23, low-refractive-index layers 42 may be configured in circular shapes, and thus, the convex portions 144 may be arranged to occupy the remaining locations.

In the above-described example, the solid-state image sensor 1 may include both the first periodic structure 32 and the second periodic structure 40. However, the solid-state image sensor 1 may not include any one of the first periodic structure 32 and the second periodic structure 40.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While examples have been particularly shown and described with reference to embodiments thereof, it will be understood that various changes in form and details may be made therein without departing from the spirit and scope of the following claims.

What is claimed is:

1. A solid-state image sensor comprising:
a substrate comprising a front side surface and a back side surface opposing the front side surface;
a plurality of photoelectric conversion units arranged two-dimensionally in the substrate;
an on-chip lens formed on the back side surface of the substrate; and
wiring layers formed on the front side surface of the substrate and comprising a first wiring layer disposed closest to the front side surface of the substrate in a vertical direction among the wiring layers,
wherein the first wiring layer comprises:
a first periodic structure arranged in a first horizontal direction in a plan view and a second horizontal direction perpendicular to the first horizontal direction in the plan view,
wherein the first periodic structure comprises a plurality of metal layers and a plurality of dielectric layers disposed between the plurality of metal layers, and
wherein the plurality of photoelectric conversion units are configured to absorb an infrared light.

2. The solid-state image sensor of claim 1, wherein the plurality of metal layers of the first periodic structure have:
an island shape in which each of the plurality of metal layers is independently arranged; or
a peninsula shape, a ring shape, or a linear shape in which the plurality of metal layers are connected to each other.

3. The solid-state image sensor of claim 1, wherein each metal layer of the plurality of metal layers of the first periodic structure comprises:
a wiring configured for a sensor operation; and
a dummy wiring.

4. The solid-state image sensor of claim 1, wherein a width of each metal layer of the plurality of metal layers of the first periodic structure in the first horizontal direction is greater than a width of each dielectric layer of the plurality of dielectric layers in the first horizontal direction.

5. The solid-state image sensor of claim 1, further comprises:
a plurality of insulating films between the plurality of photoelectric conversion units.

6. The solid-state image sensor of claim 5, wherein the plurality of insulating films are in contact with the front side surface of the substrate and the back side surface of the substrate.

7. The solid-state image sensor of claim 1, wherein a height of the first periodic structure is in a range of 100 nm to 1500 nm.

8. The solid-state image sensor of claim 1, wherein a height of the first periodic structure has a reflectance of 70% or more.

9. The solid-state image sensor of claim 1, further comprises a second periodic structure formed in an interlayer film located between the front side surface of the substrate and the first wiring layer,
wherein the second periodic structure comprises a plurality of high-refractive-index layers and a plurality of low-refractive-index layers.

10. The solid-state image sensor of claim 9, wherein the plurality of high-refractive-index layers of the second periodic structure has:
an island shape in which each high-refractive-index layer of the plurality of high-refractive-index layers is independently arranged; or
a peninsula shape, a ring shape, or a linear shape, in which the plurality of high-refractive-index layers are connected to each other.

11. The solid-state image sensor of claim 9, wherein a period of the second periodic structure is shorter than a wavelength of light, and
wherein the period of the second period structure, a wavelength of the light, and an incidence angle of the light irradiated to the second periodic structure are selected to generate diffracted light in the second periodic structure.

12. The solid-state image sensor of claim 9, wherein a first period of the second periodic structure is different in a pixel array central portion from a second period in a pixel array peripheral portion of each of the plurality of photoelectric conversion units, wherein the pixel array peripheral portion is adjacent to the pixel array central portion.

13. The solid-state image sensor of claim 9, wherein a first distance from a bottom surface of the plurality of photoelectric conversion units to a center of the first periodic structure and a second distance from the bottom surface of the plurality of photoelectric conversion units to the second periodic structure are each integer multiples of a half wavelength of incident light.

14. The solid-state image sensor of claim 9, wherein the second periodic structure has a concavo-convex shape, and
wherein a wavelength of light received by the plurality of photoelectric conversion units is 940 nm, and a height of a convex portion of the concavo-convex shape is in a range of 200 nm to 400 nm or a range of 1000 nm to 1200 nm.

15. The solid-state image sensor of claim 9, wherein the second periodic structure has a concavo-convex shape, and,
wherein a wavelength of light received by the plurality of photoelectric conversion units is 940 nm, and a height of a convex portion of the concavo-convex shape has a reflectance of 70% or more.

16. A solid-state image sensor comprising:
a substrate comprising a front side surface and a back side surface opposing the front side surface;
a plurality of photoelectric conversion units arranged two-dimensionally;
an on-chip lens formed on the back side surface of the substrate; and
wiring layers formed on the front side surface of the substrate and comprising a first wiring layer disposed closest to the front side surface of the substrate in a vertical direction among the wiring layers,
wherein the first wiring layer comprises:
a first periodic structure arranged in a first horizontal direction in a plan view and a second horizontal direction perpendicular to the first horizontal direction in the plan view,
wherein the first periodic structure comprises a plurality of metal layers and a plurality of dielectric layers disposed between the plurality of metal layers,
wherein the first periodic structure comprises a plurality of high-refractive-index layer and a plurality of low-refractive-index layers, and
wherein the plurality of photoelectric conversion units are configured to absorb an infrared light.

17. The solid-state image sensor of claim 16, wherein the plurality of high-refractive-index layers of the first periodic structure have:
an island shape in which each high-refractive-index layer of the plurality of high-refractive-index layers is independently arranged; or
a peninsula shape, a ring shape, or a linear shape in which the plurality of high-refractive-index layers are connected to each other.

18. The solid-state image sensor of claim 16, wherein a period of the first periodic structure is shorter than a wavelength of light.

19. The solid-state image sensor of claim 16, wherein a first period of the first periodic structure is different in a pixel array central portion from a second period in a pixel array peripheral portion of each of the plurality of photoelectric conversion units, wherein the pixel array peripheral portion is adjacent to the pixel array central portion.

20. The solid-state image sensor of claim 16, wherein the first periodic structure is a diffraction grating, and,
wherein a wavelength of light received by the plurality of photoelectric conversion units is 940 nm, a height of a convex portion of the diffraction grating is in a range of 200 nm to 400 nm, is in a range of 1000 nm to 1200 nm, or has a reflectance of 70% or more.
